(19) United States
(12) Patent Application Publication
(10) Pub. No.: US 2016/0315290 A1
(43) Pub. Date: Oct. 27, 2016

(54) LIGHT EMITTING DEVICE AND ORGANIC LIGHT EMITTING PANEL

(71) Applicant: EverDisplay Optronics (Shanghai) Limited, Shanghai (CN)

(72) Inventors: Mingyue ZHANG, Shanghai (CN); Chung Che TSOU, Shanghai (CN); Pingl SHIH, Shanghai (CN); Wenxiu ZHU, Shanghai (CN)

(21) Appl. No.: 15/134,447

(22) Filed: Apr. 21, 2016

(30) Foreign Application Priority Data
Apr. 21, 2015 (CN) 201510193422.X

(51) Int. Cl. H01L 51/52; H01L 27/32

(52) U.S. Cl. CPC H01L 51/5275; H01L 27/3262; H01L 27/3248; H01L 27/3246; H01L 2251/5315; H01L 2251/558; H01L 2251/301; H01L 2251/303; H01L 27/1214

(57) ABSTRACT

The invention relates to the field of Light emitting device manufacturing technology, and more particularly to a light emitting device and an organic light emitting panel, the invention sets a light extraction layer comprising at least two refractive index layers stacked successively above the array substrate of the display device, and the refractive index of the at least two refractive index layers gradually decreases from the direction close to the array substrate toward the direction away from the array substrate, thereby reducing the wide-angle color shift, optimizing the display effect, and effectively reducing the blue-violet light harmful to human eye that under 435 nm to achieve the effect of protecting eye, through changing the material of the light extraction layer from organic material in traditional technologies to inorganic material.

### CROSS-REFERENCE TO RELATED INVENTIONS

The present invention claims priority to and the benefit of Chinese Patent invention No. CN 201510193422.X, filed on Apr. 21, 2015, the entire content of which is incorporated herein by reference.

### BACKGROUND OF THE INVENTION

1. Field of the invention

The invention relates to the field of Light emitting device manufacturing technology, and more particularly, to a light emitting device and an organic light emitting panel.

2. Description of the Related Art

Organic light-emitting device PLED) has advantages of high efficiency, high brightness, low drive voltage, fast response and large area optical display, etc. OLED attracts broad attention because of its great invention prospects in the field of panel display and efficient lighting, and it is also one of the preferred clean lighting light source in 21st century.

Nowadays, with the development of OLED technologies, although the display device can meet the vast majority of people's needs, there are still some shortcomings, such as the existence of blue-violet light emitted from the display device that harms human eye; there are still wide-angle color shift and susceptible to water and oxygen corrosion problem in OLED display devices.

Light emitted from the OLED light emitting device also includes high intensity high-energy short-wave blue-violet light, and high-energy short-wave blue-violet light has high energy that can penetrate crystalline lens directly to the retina, thus free radicals of pigment epithelial cells death are generated on the retina, leading to the lack of nutrients of photosensitive cells and causing vision damage.

Currently, OLED light emitting device generally comprises an OLED module and a light extraction layer disposed on the OLED module, and the light extraction layer is a single layer of organic material and can be used to increase the light extraction efficiency of OLED module; in order to reduce the intensity of blue-violet light, typically the thickness of the organic layer of OLED light emitting device is adjusted to control the micro-resonant cavity to reduce the intensity of its emission of high-energy short-wave blue-violet light, but the adjustment range is limited, which is far less than the requirement which is not to injure human eye.

### BRIEF DESCRIPTION OF THE INVENTION

To solve the problems above, the invention discloses a light emitting device, wherein, the lighting device comprising:
a first electrode;
an organic light emitting layer, disposed on the first electrode;
a second electrode, disposed on the organic light emitting layer;
a light extraction layer, disposed on the second electrode;
wherein the light extraction layer comprises at least two refractive index layers stacked successively, and refractive indexes of the refractive index layers gradually decreases from a direction close to the second electrode toward a direction away from the second electrode.

As a preferred implementation, in the light emitting device, the first electrode is an anode, and the second electrode is a cathode.

As a preferred implementation, in the light emitting device, a light emits from the upper surface of the second electrode.

As a preferred implementation, in the light emitting device, a thickness of the light extraction layer is 200˜800 nm.

As a preferred implementation, in the light emitting device, the light extraction layer is made from inorganic compound.

As a preferred implementation, in the light emitting device, the refractive index layer is made from one or any combination of SiOₓ, SiNₓ, TiO₂, ZnS, ZnSe and ZrO.

As a preferred implementation, in the light emitting device, the light extraction layer comprises a first refractive index layer, a second refractive index layer and a third refractive index layer;
the third refractive index layer covers the second electrode, the second refractive index layer covers an upper surface of the third refractive index layer, the first refractive index layer covers an upper surface of the second refractive index layer;
wherein, a refractive index of the third refractive index layer is larger than a refractive index of the second refractive index layer, and a refractive index of the second refractive index layer is larger than a refractive index of the first refractive index layer.

As a preferred implementation, in the light emitting device, the first refractive index layer is made from SiOx, the second refractive index layer is made from SiNx, the third refractive index layer is made from ZnSe.

As a preferred implementation, in the light emitting device, a refractive index of the first refractive layer is from 1.2 to 1.5, a refractive index of the second refractive index layer is from 1.7 to 2.0, a refractive index of the third refractive index layer is from 2.2 to 2.6.

The invention also discloses an organic light emitting panel, comprising:
an array substrate, including a substrate and a plurality of thin film transistor array disposed on the substrate;
a first electrode, disposed on the array substrate, and the first electrode being electrically connected to at least one of the thin film transistors of the array substrate;
a pixel design layer, disposed on the first electrode, and the pixel design layer having an opening exposing a portion of the first electrode;
an organic light emitting layer, at least partially disposed on the first electrode which is exposed by the opening;
a second electrode, disposed on the pixel design layer and the organic light emitting layer;
a light extraction layer disposed on the second electrode;
an opposite substrate disposed on the light extraction layer, and there is a gap between the opposite substrate and the light extraction layer;
wherein the light extraction layer comprises at least two refractive index layers stacked successively, and refractive indexes of the refractive index layers gradually decreases from a direction close to the second electrode toward a direction away from the second electrode.

As a preferred implementation, in the organic light emitting panel, the light extraction layer is made from inorganic compound.

As a preferred implementation, in the organic light emitting panel, the refractive index layer is made from one or any combination of SiOₓ, SiNₓ, TiO₂, ZnS, ZnSe and ZrO.

As a preferred implementation, in the organic light emitting panel, the light extraction layer comprises a first refractive index layer, a second refractive index layer and a third refractive index layer;
the third refractive index layer covers the second electrode, the second refractive index layer covers an upper surface of the third refractive index layer, the first refractive index layer covers an upper surface of the second refractive index layer;
wherein, a refractive index of the third refractive index layer is larger than a refractive index of the second refractive index layer, and a refractive index of the second refractive index layer is larger than a refractive index of the first refractive index layer.

As a preferred implementation, in the organic light emitting panel, the first refractive index layer is made from SiOx, the second refractive index layer is made from SiNx, the third refractive index layer is made from ZnSe.

As a preferred implementation, in the organic light emitting panel, a refractive index of the first refractive layer is from 1.2 to 1.5, a refractive index of the second refractive index layer is from 1.7 to 2.0, a refractive index of the third refractive index layer is from 2.2 to 2.6.

As a preferred implementation, in the organic light emitting panel, a thickness of the light extraction layer is 200˜800 nm.

As a preferred implementation, in the organic light emitting panel, a light emits from the upper surface of the second electrode.

As a preferred implementation, in the organic light emitting panel, the first electrode is an anode, and the second electrode is a cathode.

As a preferred implementation, in the organic light emitting panel, a light emits from the upper surface of the opposite substrate.

The invention has the following advantages and beneficial effects:
the technical solution of the invention is based on the traditional light emitting device, and sets a light extraction layer comprising at least two refractive index layers stacked successively on the array substrate of the display device, and the refractive index of the refractive index layers gradually decreases from a direction close to the array substrate toward a direction away from the array substrate, thereby the wide-angle color shift is reduced, the display effect optimized, and the blue-violet light harmful to human eye, which is under 435 nm, is effectively reduced to achieve the effect of protecting eye; through changing the material of the light extraction layer from organic material in traditional technologies to inorganic material, thereby enhancing the barrier effect against water and oxygen, since the inorganic material has better barrier properties against water and oxygen, and further improving the effect of OLED encapsulation.

### BRIEF DESCRIPTIONS OF THE DRAWINGS

The accompanying drawings, together with the specification, illustrate exemplary embodiments of the present disclosure, and, together with the description, serve to explain the principles of the present invention.

FIG. 1 is a structural diagram of the light emitting device of an embodiment of the invention;

FIG. 2 is a structural diagram of the light emitting panel of an embodiment of the invention;

FIG. 3 is a contrast diagram about the light emitted from the light emitting device prepared by the technical solution of the invention and the conventional light emitting device;

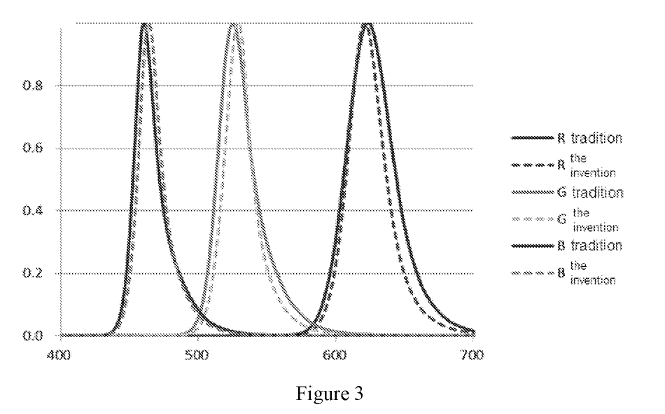

Wherein, in FIG. 3 the abscissa represents the wavelength of light, the unit is nm; the ordinate represents the frequency of light, the unit is cps; the solid line is the schematic view of the conventional light emitting device emitting light, while the dashed line is the schematic view of the light emitting device of the invention emitting light.

### DETAILED DESCRIPTIONS

The present invention will now be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used herein, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As used herein, “around”, “about” or “approximately” shall generally mean within 20 percent, preferably within 10 percent, and more preferably within 5 percent of a given value or range. Numerical quantities given herein are approximate, meaning that the terra “around”, “about” or “approximately” can be inferred if not expressly stated.

As used herein, the term “plurality” means a number greater than one.

Hereinafter, certain exemplary embodiments according to the present disclosure will be described with reference to the accompanying drawings.

The light emitting device and the organic light emitting panel provided by the embodiment of the invention is based on the traditional light emitting device, and sets a light extraction layer comprising multiple (at least two) refractive index layers stacked successively on the surface of the screen module i.e. the light-emitting surface), and refractive indexes of the multiple refractive index layers gradually decreases according to the order from bottom to top along a direction perpendicular to the surface of the front of the screen module, thereby reducing the wide-angle color shift, optimizing the display effect, and effectively reducing the blue-violet light harmful to human eye, which is under 435 nm, to achieve the effect of protecting eye, using the inorganic material to prepare the light extraction layer can also enhance the barrier effect against water and oxygen, and further improve the effect of OLED encapsulation.

Below in conjunction with the accompanying drawings and specific embodiments to further illustrate the invention, but is not intended to limit the invention.

### First Embodiment

FIG. 1 is a profile structure diagram of the light emitting device of an embodiment of the invention. As show in FIG. 1, the embodiment relates to a light emitting device, comprising: the display module 1 and the light extraction layer 2; the above-mentioned display module 1 having a light-emitting front and back opposite to the front, the light extraction layer 2 being set on the front of the screen module 1; wherein the light extraction layer comprises at least two refractive index layers stacked successively (e.g., the light extraction layer comprises two stacked refractive index layers, three stacked refractive index layers, four stacked refractive index layers, five or six stacked refractive index layers), and refractive indexes of the refractive index layers gradually decreases according to the order from bottom to top along a direction perpendicular to the surface of the front of the screen module 1 (i.e. the farther the refractive index layer is from the screen module 1, the smaller the refractive index is); using the light extraction layer 2 comprising multiple refractive index layers, of which refractive indexes decreases successively, to prepare the display device can effectively reduce the high-energy short-wave blue-violet light emitting from the light emitting device that harms human eye; e.g. for the blue-violet light of which the wavelengths is less than 435 nm, the effect is more obvious.

In a preferred embodiment of the invention, the above-described light emitting device further comprises a substrate (the substrate is not shown in the figure). The display module 1 is provided on the surface of the substrate.

On this basis, further, the above-described screen module 1 may be a conventional AMOLED, comprising an anode 11, an organic light emitting layer 12 and a cathode 13; the anode (ITO/Ag/ITO) 11 is configured on the substrate, the organic light emitting layer 12 is configured on the anode 11, the cathode (Mg/Ag) 13 is configured on the organic light emitting layer 12, and the upper surface of the cathode 13 can be used as a front that emits light, thereby the lower surface of the anode 11 can be used as a back opposite to the front, that is to say, the organic light emitting layer is located between the anode and the metal cathode, and the light extraction layer 2 is configured on the cathode 13.

In a preferred embodiment of the invention, the above-described organic light emitting layer 12 includes a first hole injection layer (HIL) 121, a second hole injection layer 122, a third hole injection layer 123, an hole transport layer (HTL) 124, an emitting layer (EML) 125 and an electron transport layer (ETL) 126; the first hole injection layer 121 is disposed over the anode 11, the second hole injection layer 122 is disposed on the first hole injection layer 121, the third hole injection layer 123 is disposed on the second hole injection layer 122, the hole transport layer 124 is disposed on the third hole injection layer 123, the emitting layer 125 is disposed on the hole transport layer 124, the electron transport layer 126 is disposed on the emitting layer 125; the emitting layer 125 is used for emitting light, and the light successively passes across the electron transport layer 126, the cathode 13 and the light extraction layer 2 and emits out; or, the light emitting from the emitting layer 125 may be successively across the hole transport layer 124, the third hole injection layer 123, the second hole injection layer 122 and the first hole injection layer 121 and lights (downward) to the surface of the anode 11, then the anode 11 reflects the light lighted to its surface, the reflected light successively passes through the above-described organic layer 12, the cathode 13 and the light extraction layer 2 and emits out upwardly.

In a preferred embodiment of the invention, the thickness of the above-described light extraction layer 2 is 200˜800 nm (e.g. 200 nm, 300 nm, 500 nm or 800 nm, etc.); wherein, the specific thickness of each refractive index layer is required to match the length of the optical cavity of the device, it may be a uniform thickness or may not be a uniform thickness, which does not affect the object of the invention.

In a preferred embodiment of the invention, the material of the above-described light extraction layer is inorganic compound, compared to the organic light extraction layer of conventional techniques, the inorganic material has better barrier effect against water and oxygen, thus inorganic material can enhance the inorganic material of the light emitting device prepared by the inorganic light extraction layer of the embodiment, and further enhance the effect of the OLED encapsulation.

On this basis, further, the refractive index layers may be made from one or any combination of SiOₓ, SiNₓ, TiO₂, ZnS, ZnSe and ZrO,

In a preferred embodiment of the invention, low-temperature CVD process is used to prepare light extraction layer 2; although the cost of low-temperature CVD process for producing the light extraction layer 2 is slightly higher, but low-temperature CVD process Will reduce the secondary damage and interference to the device, since the process insures low temperature in process, while traditional process, such as sputtering and so on, will hurt the device because of higher temperature and its greater intensity.

In a preferred embodiment of the invention, the above-described light extraction layer 2 comprises a first refractive index layer, a second refractive index layer and a third refractive index layer; the third refractive index layer covers the front of the screen module, the second refractive index layer covers the upper surface of the third refractive index layer, the first refractive index layer covers the upper surface of the second refractive index layer.

Preferably, the above-described light extraction layer 2 comprises three refractive index layers stacked successively, the three refractive index layers are the third refractive index layer, the second refractive index layer and the first refractive index layer according to the order from bottom to top along the direction perpendicular to the front of the screen module; assuming a refractive index of the third refractive index layer is n3, a refractive index of the second refractive index layer is n2, a refractive index of the first refractive index layer is n1, n1 <n2 <n3, namely the refractive indexes of the three refractive index layers decreases in turn according to the order from bottom to top along the direction perpendicular to the front of the screen module.

Specifically, the refractive index n1 of the first refractive index layer is from 1.2 to 1.5 (e.g. 1.2, 1.3, 1.4 or 1.5, etc.), the refractive index n2 of the second refractive index layer is from 1.7 to 2.0 (e.g. 1.7, 1.8, 1.9 or 2.0, etc.), the refractive index n3 of the third refractive index layer is from 2.2 to 2.6 (e.g. 2.2, 2.3, 2.5 or 2.6, etc.).

Preferably, the first refractive index layer is made from SiOx and other materials, the second refractive index layer is made from SiNx and other materials, the third refractive index layer is made from ZnSe and other materials.

In addition, based on the traditional technology, the following process can be used to prepare the structure shown in FIG. 1, and in particular:

Firstly, providing a screen module 1, and the screen module 1 having a front for emitting light; the screen module 1 may be based on AMOLED prepared by the traditional process, as the structure shown in FIG. 1, the screen module 1 comprises the anode 11, the organic light emitting layer 12 disposed on the anode (ITO/Ag/ITO) 11, the cathode (Mg/Ag) 13 disposed on the organic light emitting layer 12, and the upper surface of the cathode 13 can be used as the light-emitting front, then the lower surface of the anode 11 can be used as the back opposite to the front.

Secondly, preparing at least two refractive index layers stacked successively on the front of the screen module as the light extraction layer 2 of the screen module, wherein refractive indexes of the refractive index layers gradually decreases according to the order from bottom to top along the direction perpendicular to the surface of the screen module 1, namely:
low-temperature CVD process can be used to successively prepare the third refractive index layer, the second refractive index layer and the first refractive index layer of which refractive indexes gradually decreases (i.e. the refractive index of the third refractive index layer is larger than the refractive index of the second refractive index layer, and the refractive index of the second refractive index layer is larger than the refractive index of the first refractive index layer) on the screen module 1, so as to form the light extraction layer 2 comprising the three refractive index layers; using the low-temperature CVD process to prepare the light extraction layer 2 can effectively reduce secondary damage and interference to the device, thereby improving product yield.

FIG. 3 is a contrast diagram about the light emitted from the light emitting device prepared by the technical solution of the invention and the conventional light emitting device; comparing the light emitted from the light emitting device prepared by conventional light extraction layer and the light emitting from the light emitting device prepared by light extraction layer 2 of the invention by optical simulation, as shown in FIG. 3, the light spectrum of the light emitting device prepared by the light extraction layer of the invention generates red shift compared to the light emitting device prepared by conventional light extraction layer, and the emission wavelength becomes longer, thus the energy of blue-violet light under 435 nm can be greatly reduced (as shown in FIG. 3, by using this invention, the energy of blue-violet light under 435 nm can be 30% lower compared to the conventional structure), and the NTSC color gamut of the device is increased from the original 112% to 115%; meanwhile, it can be known from FIG. 3 that the light spectrum of the light emitting device (R/G/B dotted line) prepared by the light extraction layer of the invention has a smaller full width at half maximum (FWHM) compared to the light emitting device (R/G/B solid line) prepared by conventional light extraction layer, so the light emitted from the emitting device of the invention has higher color purity, and the invention can improve NTSC of the device from 112% to 115%.

### Second Embodiment

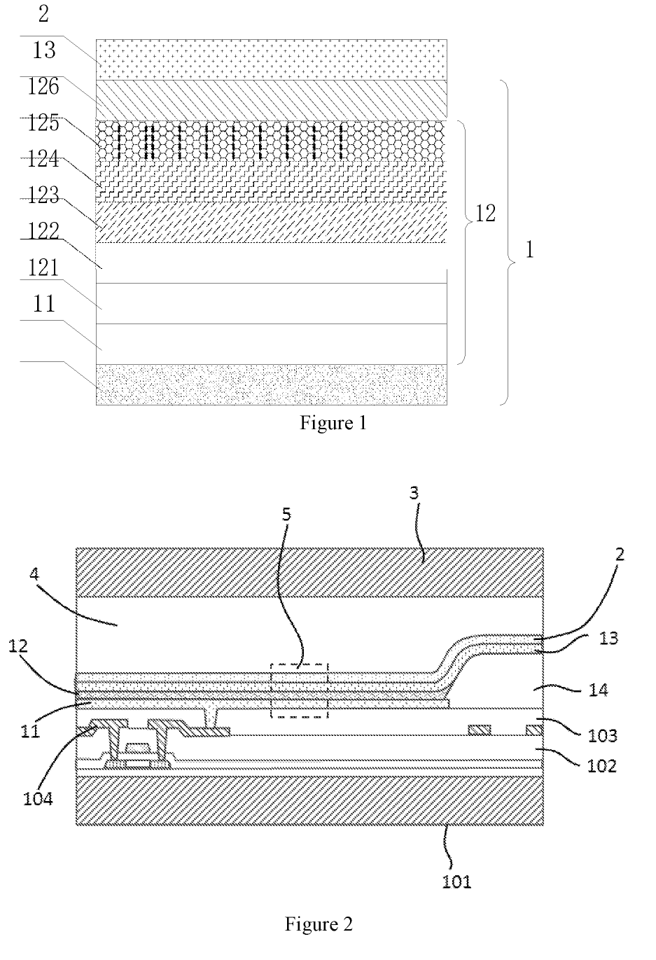

FIG. 2 is a structural diagram of light emitting panel of an embodiment of the invention; as shown in FIG. 2, the invention also describes an organic light emitting panel, comprising the array substrate 101, the insulating layer 102 and the planarization layer 103; the insulating layer 102 and the planarization layer 103 are on the array substrate 101; the array substrate 101, the insulating layer 102 and the planarization layer 103 can be used as a substrate structure of the light emitting device preparing subsequently; preferably, the substrate structure is prepared with a number of thin film transistor array 104.

Further, the above-described organic light emitting panel further includes a first electrode 11, an organic light emitting layer 12, a second electrode 13 and a pixel design layer 14; the first electrode 11 is disposed on the planarization layer 103 and electrically connects to at least one thin film transistor through a wire throughout the planarization layer 103; the pixel design layer 14 is disposed on the first electrode 11, and the pixel design layer 14 has an opening exposing a portion of the first electrode 11 (not shown in figure); the organic light emitting layer 12 is partly disposed on the first electrode which is exposed by the opening; the second electrode 13 is disposed on the pixel design layer 14 and the organic light emitting layer 12.

Preferably, when the first electrode 11 is an anode, the second electrode 13 is a cathode, correspondingly, when the first electrode 11 is a cathode, the second electrode 13 is an anode.

Further, the above-described organic emitting panel further includes the light extraction layer 2 disposed on the second electrode 13 and the opposite substrate 3 disposed on the light extraction layer 2; wherein there is a gap 4 between the opposite substrate 3 and the light extraction layer 2; meanwhile, the light extraction layer 2 comprises at least two refractive index layers stacked successively, and refractive indexes of the refractive index layers gradually decreases from a direction close to the second electrode 13 to the direction away from the second electrode 13, therefore the wide-angle color shift of the light emitted from the organic light emitting panel is reduced, and the effect of display of the organic light emitting panel is optimized, and meanwhile the blue-violet light in the light emitted from the organic light emitting panel that under 435 nm and harmful to human eye is effectively reduced to achieve the effect of protecting eye.

Preferably, the above-described light extraction layer 2 is made from inorganic compound; since the organic material has better barrier properties against water and oxygen compared to the organic material, the barrier properties against water and oxygen of the device prepared by the inorganic light extraction layer and the effect of OLED encapsulation can be enhanced.

FIG. 3 is a contrast diagram about the light emitted from the light emitting device prepared by the technical solution of the invention and the conventional light emitting device; comparing the light emitting from the light emitting device prepared by conventional light extraction layer and the light emitting from the light emitting device prepared by light extraction layer 2 of the invention by optical simulation, as shown in FIG. 3, the light spectrum of the light emitted from the light emitting device prepared by the light extraction layer of the invention generates red shift compared to the light emitting device prepared by conventional light extraction layer, and the emission wavelength becomes longer, thus the energy of blue-violet light under 435 nm can be greatly reduce, and the NTSC color gamut of the device can increased from the original 112% to 115%; meanwhile, it can be known from FIG. 3 the light spectrum of the light emitting device (R/G/B dotted line) prepared by the light extraction layer of the invention has a smaller full width at half maximum (FWHM) compared to the light emitting device (R/G/B solid line) prepared by conventional light extraction layer, so the light emitted from the emitting device of the invention has higher color purity.

Referring to FIGS. 1 and 2, the embodiment may correspond to the above-described embodiment, i.e., FIG. 1 can be regarded as an enlarged schematic view of the specific structure of the region 5 in FIG. 2, and the same numerals indicate the same structure, so the embodiment can be carried out cooperate with the embodiment of the light emitting device. The technical details mentioned in the embodiment of the light emitting device are still valid in this embodiment, so it is not repeated here in order to reduce duplication. Accordingly, the technical details mentioned in this embodiment can also be applied in the embodiment of the light emitting device.

In summary, the light emitting device and the organic light emitting panel provided in the invention sets a light extraction layer comprising at least two refractive index layers stacked successively on the front of the screen module, and the refractive indexes of the refractive index layers gradually decreases according to the order from bottom to top along the direction perpendicular to the front surface of the screen module, therefore the wide-angle color shift is reduced, the display effect is optimized, and the blue-violet light harmful to human eye, which is under 435 nm, is effectively reduced to achieve the effect of protecting eye, and the barrier effect against water and oxygen and the effect of OLED encapsulation are improved.

The foregoing is only the preferred embodiments of the invention, not thus limiting embodiments and scope of the invention, those skilled in the art should be able to realize that the schemes obtained from the content of specification and figures of the invention are within the scope of the invention.

What is claimed is:

1. A light emitting device, comprising:
a first electrode;
an organic light emitting layer, disposed on the first electrode;
a second electrode, disposed on the organic light emitting layer;
a light extraction layer disposed on the second electrode;
wherein, the light extraction layer comprises at least two refractive index layers stacked successively, and refractive indexes of the refractive index layers gradually decreases from a direction close to the second electrode toward a direction away from the second electrode.

2. The light emitting device according to claim 1, wherein the first electrode is an anode, and the second electrode is a cathode.

3. The light emitting device according to claim 1, wherein a light emits from the upper surface of the second electrode.

4. The light emitting device according to claim 1, wherein a thickness of the light extraction layer is 200˜800 nm.

5. The light emitting device according to claim 1, wherein the light extraction layer is made from inorganic compound.

6. The light emitting device according to claim 4, wherein the refractive index layer is made from one or any combination of SiOₓ, SiNₓ, TiO₂, ZnS, ZnSe and ZrO.

7. The light emitting device according to claim 1, wherein the light extraction layer comprises a first refractive index layer, a second refractive index layer and a third refractive index layer;
the third refractive index layer covers the second electrode, the second refractive index layer covers an upper surface of the third refractive index layer, the first refractive index layer covers an upper surface of the second refractive index layer;
wherein, a refractive index of the third refractive index layer is larger than a refractive index of the second refractive index layer, and the refractive index of the second refractive index layer is larger than a refractive index of the first refractive index layer.

8. The light emitting device according to claim 7, wherein the first refractive index layer is made from SiOx, the second refractive index layer is made from SiNx, the third refractive index layer is made from ZnSe.

9. The light emitting device according to claim 7, wherein a refractive index of the first refractive layer is from 1.2 to 1.5, a refractive index of the second refractive index layer is from 1.7 to 2.0, a refractive index of the third refractive index layer is from 2.2 to 2.6.

10. An organic light emitting panel, comprising:
an array substrate, including a substrate and a plurality of thin film transistor array disposed on the substrate;
a first electrode, disposed on the array substrate, and the first electrode being electrically connected to at least one of the thin film transistors of the array substrate;
a pixel design layer, disposed on the first electrode, and the pixel design layer having an opening exposing a portion of the first electrode;
an organic light emitting layer, at least partially disposed on the first electrode which is exposed by the opening;
a second electrode, disposed on the pixel design layer and the organic light emitting layer;
a light extraction layer, disposed on the second electrode;
an opposite substrate, disposed on the light extraction layer, and there is a gap between the opposite substrate and the light extraction layer;
wherein the light extraction layer comprises at least two refractive index layers stacked successively, and refractive indexes of the refractive index layers gradually decreases from a direction close to the second electrode toward a direction away from the second electrode.

11. The organic light emitting panel according to claim 10, wherein the light extraction layer is made from inorganic compound.

12. The organic light emitting panel according to claim 11, wherein the refractive index layer is made from one or any combination of SiOₓ, SiNₓ, TiO₂, ZnS, ZnSe, and ZrO.

13. The organic light emitting panel according to claim 12, wherein the light extraction layer comprises a first refractive index layer, a second refractive index layer and a third refractive index layer;
the third refractive index layer covers the second electrode, the second refractive index layer covers an upper surface of the third refractive index layer, the first refractive index layer covers an upper surface of the second refractive index layer;
wherein, a refractive index of the third refractive index layer is larger than a refractive index of the second refractive index layer, and the refractive index of the second refractive index layer is larger than a refractive index of the first refractive index layer.

14. The organic light emitting panel according to claim 13, wherein the first refractive index layer is made from SiOx, the second refractive index layer is made from SiNx, the third refractive index layer is made from ZnSe.

15. The organic light emitting panel according to claim 14, wherein a refractive index of the first refractive layer is from 1.2 to 1.5, a refractive index of the second refractive index layer is from 1.7 to 2.0, a refractive index of the third refractive index layer is from 2.2 to 2.6.

16. The organic light emitting panel according to claim 10, wherein a thickness of the light extraction layer is 200˜800 nm.

17. The organic light emitting panel according to claim 10, wherein a light emits from the upper surface of the second electrode.

18. The organic light emitting panel according to claim 17, wherein the first electrode is an anode, and the second electrode is a cathode.

19. The organic light emitting panel according to claim 10, wherein a light emits from the upper surface of the opposite substrate.
